(19) United States
(12) Patent Application Publication
(10) Pub. No.: US 2024/0248148 A1
(43) Pub. Date: Jul. 25, 2024

(54) DETECTION OF BATTERY PACK MIS-ASSEMBLY

(71) Applicant: Caterpillar Inc., Peoria, IL (US)

(72) Inventors: Alexander C. CROSMAN, III, Dunlap, IL (US); Jason Lee MILLER, Princeville, IL (US); Saneeb UMMER, Dunlap, IL (US)

(73) Assignee: Caterpillar Inc., Peoria, IL (US)

(21) Appl. No.: 18/159,519

(22) Filed: Jan. 25, 2023

(51) Int. Cl. G01R 31/396; G06F 13/20

(52) U.S. Cl. CPC G01R 31/396; G06F 13/20; G06F 2213/40

(57) ABSTRACT

In some implementations, a controller may provide first instructions to a plurality of measurement devices, wherein the plurality of measurement devices are configured to obtain measurements from a plurality of battery modules of a battery pack. The controller may receive one or more first responses from one or more first measurement devices of the plurality of measurement devices based on providing the first instructions, wherein the one or more first responses include first unique identifier information identifying one or more first unique identifiers associated with the one or more first measurement devices. The controller may determine, based on the one or more first unique identifiers, whether the plurality of battery modules are improperly assembled.

### TECHNICAL FIELD

The present disclosure relates generally to a battery pack of a work machine and, for example, to a battery management system that detects mis-assembly of battery modules of the battery pack.

### BACKGROUND

A battery pack, of a work machine, may include multiple battery modules. The battery modules may be connected in series and/or in parallel to meet a particular need (e.g., a particular voltage, a particular current, a particular total energy, among other examples). Multiple monitoring boards may be connected to the battery modules to obtain measurements of the battery modules.

The monitoring boards may be connected, via a data bus, to a controller of a battery management system. Connections, via the data bus, from the monitoring boards to the controller are to be provided in specific ways according to a configuration of the battery pack. In some instances, the connections are made in a ring format with the battery modules connected in series and the data bus connected to a first port and a second port of the controller.

In some instances, the battery modules may be misassembled. For example, too many battery modules may be connected to the data bus. Alternatively, not enough battery modules may be connected to the data bus. Alternatively, the battery modules may be connected out of order on the data bus. Typically, the controller is unable to detect that the battery modules are misassembled. The inability to detect mis-assembly of the battery modules may cause one or more components of the work machine to operate in an undesired manner. For example, the inability to detect mis-assembly of the battery modules may lead to inaccurate battery state estimations, battery damage, and/or battery failure.

U.S. patent Application Publication No. 20220276312 (the '312 publication) discloses detecting connection failure of a parallel connected cell. For example, the '312 publication discloses first detecting the cell connection failure due to the current interruption device (CID) operation of the battery or opening the parallel connection line for a battery that is being discharged by the operation of an external device. The '312 publication further discloses confirming the first detection result through direct current internal resistance (DCIR) measurement for the battery.

While the '312 publication discloses detecting connection failure of a parallel connected cell, the '312 publication does not disclose detecting that battery modules (of a battery pack) are misassembled.

The battery management system of the present disclosure solves one or more of the problems set forth above and/or other problems in the art.

### SUMMARY

In some implementations, a battery management system configured to detect mis-assembly of a battery pack includes a data bus; a plurality of measurement devices configured to obtain measurements from a plurality of battery modules of the battery pack, wherein the plurality of measurement devices are connected to the data bus; and a controller, connected to the data bus, configured to: provide first instructions to the plurality of measurement devices, receive one or more first responses from one or more first measurement devices of the plurality of measurement devices based on providing the first instructions, wherein the one or more first responses include first unique identifier information identifying one or more first unique identifiers associated with the one or more first measurement devices; provide second instructions to the plurality of measurement devices, receive one or more second responses from one or more second measurement devices of the plurality of measurement devices based on providing the second instructions, wherein the one or more second responses include second unique identifier information identifying one or more second unique identifiers associated with the one or more second measurement devices; and determine whether the plurality of battery modules are improperly assembled based on the first unique identifier information and the second unique identifier information.

In some implementations, a machine includes a data bus; a plurality of measurement devices configured to obtain measurements from a plurality of battery modules of a battery pack, wherein the plurality of measurement devices are connected to the data bus; and a controller, connected to the data bus, configured to: provide first instructions to the plurality of measurement devices, receive one or more first responses from one or more first measurement devices of the plurality of measurement devices based on providing the first instructions, wherein the one or more first responses include first unique identifier information identifying one or more first unique identifiers associated with the one or more first measurement devices; provide second instructions to the plurality of measurement devices, receive one or more second responses from one or more second measurement devices of the plurality of measurement devices based on providing the second instructions, wherein the one or more second responses include second unique identifier information identifying one or more second unique identifiers associated with the one or more second measurement devices; compare the first unique identifier information and the second unique identifier information; and determine whether the plurality of battery modules are improperly assembled based on comparing the first unique identifier information and the second unique identifier information.

In some implementations, a method performed by a controller includes providing first instructions to a plurality of measurement devices, wherein the plurality of measurement devices are configured to obtain measurements from a plurality of battery modules of a battery pack; receiving one or more first responses from one or more first measurement devices of the plurality of measurement devices based on providing the first instructions, wherein the one or more first responses include first unique identifier information identifying one or more first unique identifiers associated with the one or more first measurement devices; and determining, based on the one or more first unique identifiers, whether the plurality of battery modules are improperly assembled.

### BRIEF DESCRIPTION OF THE DRAWINGS

FIG. 1 is a diagram of an example machine described herein.

FIG. 2 is a diagram of an example system described herein.

FIG. 3 is a diagram of an example associated with detecting battery pack mis-assembly.

FIG. 4 is a diagram of an example associated with detecting battery pack mis-assembly.

FIG. 5 is a diagram of an example associated with detecting battery pack mis-assembly.

FIG. 6 is a diagram of an example associated with detecting battery pack mis-assembly.

FIG. 7 is a diagram of an example associated with detecting battery pack mis-assembly.

FIG. 8 is a diagram of an example associated with detecting battery pack mis-assembly.

FIG. 9 is a flowchart of an example processes relating to detecting battery pack mis-assembly.

### DETAILED DESCRIPTION

Implementations described herein are directed to a controller, of a battery management system, that is configured to detect whether battery modules are misassembled. The battery modules may be included in a battery pack and may be connected to measurement devices. The measurement devices may be connected to the controller in a ring format via a data bus. For example, the data bus may be connected to a first port and a second port of the controller. The battery management system and the battery pack may be included in a work machine to power the work machine.

In some implementations, the controller may provide instructions to measurement devices connected to the battery modules. For example, the instructions may be provided via the first port and/or via the second port. The controller may use the instructions to query information stored in non-volatile memories of the measurement devices. The information, stored by a non-volatile memory of a measurement device, may include a unique identifier associated with the measurement device. In some examples, the non-volatile memory may include an electrically erasable programmable read-only memory (EEPROM). Additionally, in some examples, the unique identifier may be a serial number. The unique identifier may include a unique combination of characters (e.g., alphanumeric characters).

Based on the instructions, the controller may receive one or more responses from one or more of the measurement devices. The one or more responses may include unique identifier information identifying one or more unique identifiers associated with the one or more measurement devices. As an example, the one or more unique identifiers may be one or more unique identifiers of one or more battery modules connected to the one or more measurement devices. Alternatively, the one or more unique identifiers may be one or more unique identifiers of the one or more measurement devices. As an example, the one or more unique identifiers may be one or more serial numbers. The controller may determine whether the measurement devices are misassembled based on the unique identifier information.

In some situations, the controller may determine whether the battery modules are assembled in an incorrect order. For example, the controller may receive unique identifiers in an actual order in which the battery modules are assembled in the battery pack. In this regard, the controller may compare the actual order in which the measurement devices are assembled and an expected order in which the battery modules are expected to be assembled in the battery pack. Information identifying the expected order may be stored in a memory associated with the controller. Based on detecting that the actual order is different than the expected order, the controller may determine that the battery modules are misassembled.

In some examples, the controller may determine whether an actual number of the battery modules is different than an expected number of the battery modules. For example, the controller may provide first instructions to the measurement devices via the first port and provide second instructions to the measurement devices via the second port. The controller may receive, via the first port, one or more first responses from one or more first measurement devices of the measurement devices. The controller may receive, via the second port, one or more second responses from one or more second measurement devices of the measurement devices.

The one or more first responses may include first unique identifier information identifying one or more first unique identifiers associated with the one or more first measurement devices. The one or more second responses may include second unique identifier information identifying one or more second unique identifiers associated with the one or more second measurement devices. The controller may compare the one or more first unique identifiers and the one or more second unique identifiers to determine whether the actual number of the battery modules is different than the expected number of the battery modules.

The term “machine” may refer to a device that performs an operation associated with an industry such as, for example, mining, construction, farming, transportation, or another industry. Moreover, one or more implements may be connected to the machine. As an example, a machine may include a construction vehicle, a work vehicle, or a similar vehicle associated with the industries described above.

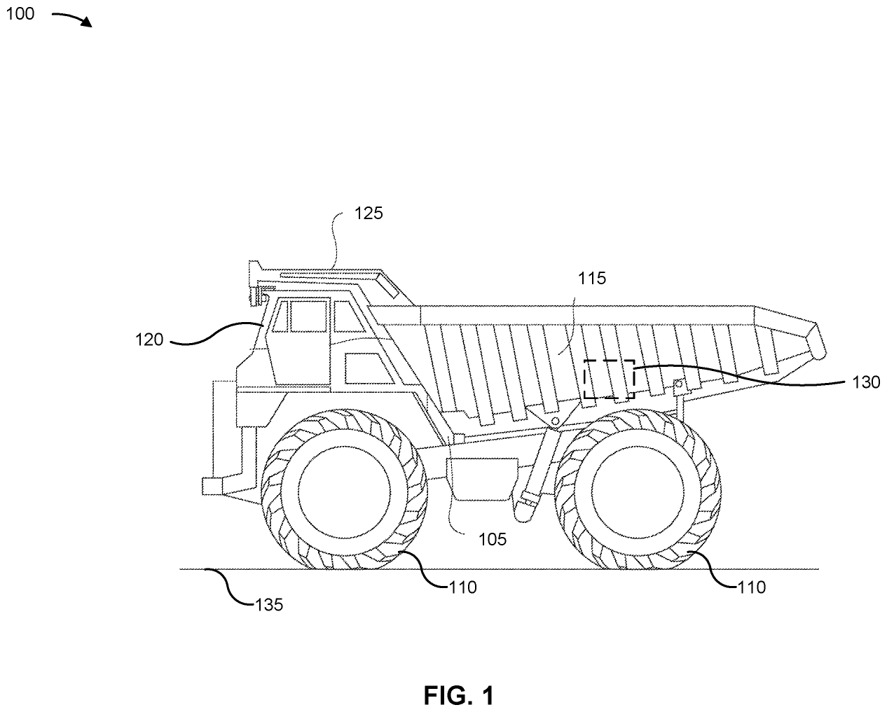

FIG. 1 is a diagram of an example machine 100 described herein. As shown in FIG. 1, machine 100 is embodied as an earth moving machine, such as a mining vehicle. Alternatively, machine 100 may be another type of machine, such as an excavator, a wheel loader, an underground loader, among other examples.

As shown in FIG. 1, machine 100 includes a frame 105, ground engaging members 110, a truck body 115, an operator cabin 120, a canopy 125, and a battery management system (BMS) 130. Frame 105 may be configured to connect to ground engaging members 110 and to support operator cabin 120. Ground engaging members 110 may be configured to propel machine 100 located on a ground surface 135 at a job site. Ground engaging members 110 may include wheels, tracks, rollers, and/or similar components, for propelling machine 100.

Truck body 115 may be capable of receiving and dumping a load. Truck body 115 may include a canopy 125. As machine 100 carries the load to a destination associated with the load, truck body 115 may pivot about frame 105 to discharge the load via a rearward opening of truck body 115.

Operator cabin 120 includes an integrated display (not shown) and operator controls. The operator controls may include one or more input components (e.g., integrated joysticks, push-buttons, control levers, and/or steering wheels) to control an operation of machine 100. For example, the operator controls may be used to control an operation of ground engaging members 110.

In some examples, BMS 130 may include a controller and multiple measurement devices connected to the controller via a data bus. The measurement devices may be connected to multiple battery modules of a battery pack and may obtain measurements from the battery modules. The battery modules may provide electrical power to support operations of machine 100. The controller may be configured to determine whether the battery modules are misassembled, as described herein.

As indicated above, FIG. 1 is provided as an example. Other examples may differ from what was described in connection with FIG. 1.

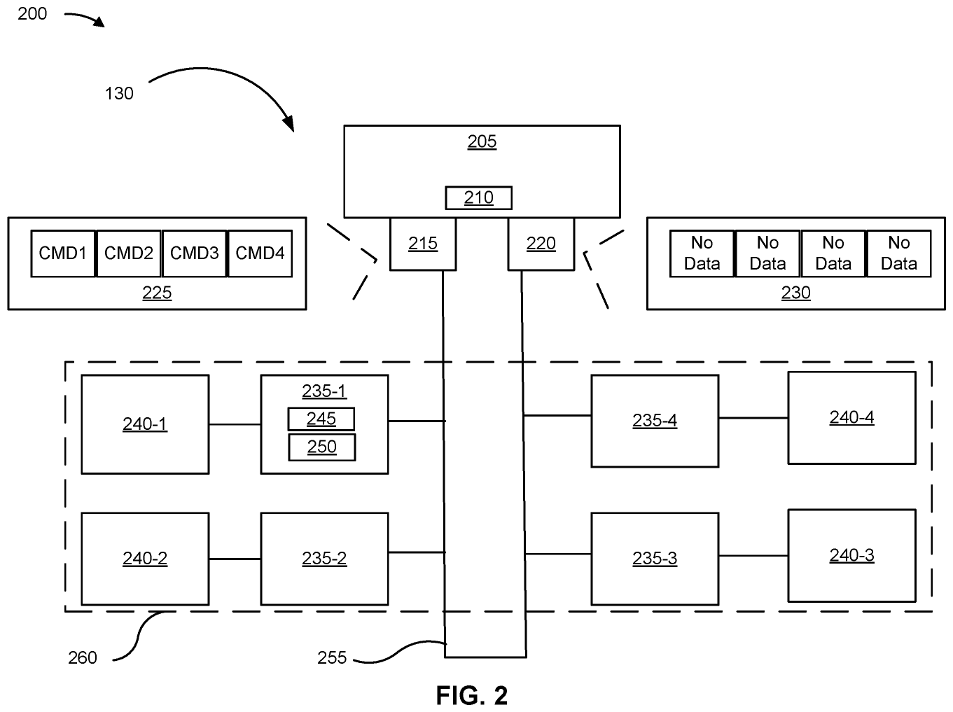

FIG. 2 is a diagram of an example system 200 described herein. As shown in FIG. 2, system 200 includes BMS 130. BMS 130 may include a controller 205 and a plurality of measurement devices connected to controller 205 via a data bus 255. The plurality of measurement devices may include a first measurement device 235-1, a second measurement device 235-2, a third measurement device 235-3, a fourth measurement device 235-4, and so on (collectively “measurement devices 235” and individually “measurement device 235”). Measurement devices 235 may be connected to a plurality of battery modules of a battery pack 260. The plurality battery modules may include a first battery module 240-1, a second battery module 240-2, a third battery module 240-3, a fourth battery module 240-4, and so on (collectively “battery modules 240” and individually “battery module 240”).

As shown in FIG. 2, controller 205 may include a memory 210, a first port 215, and a second port 220. Memory 210 includes a random-access memory (RAM), a read only memory (ROM), and/or another type of dynamic or static storage device (e.g., a flash memory, a magnetic memory, and/or an optical memory) that stores information and/or instructions for use by a processor (of controller 205) to perform a function, such detecting whether battery modules 240 of machine 100 are misassembled.

In some examples, memory 210 may include battery module information regarding battery modules 240 to which measurement devices 235 are configured to be connected. The battery module information may identify an expected number of battery modules 240 to which measurement devices 235 are configured to be connected (e.g., an expected number of battery modules 240 included in battery pack 260). Additionally, or alternatively, the battery module information may identify an expected order in which the battery modules 240 are expected to be assembled (e.g., in battery pack 260).

As shown in FIG. 2, first port 215 and second port 220 may be connected to data bus 255. For example, first port 215 may be connected to a first end of data bus 255 and second port 220 may be connected to a second end of data bus 255. In this regard, battery modules 240 may be connected to controller 205 (via measurement devices 235 and data bus 255) in series in a ring format.

As shown in FIG. 2, first port 215 may be associated with a first data structure 225. First data structure 225 may be configured to store instructions (generated by controller 205) to be provided to measurement devices 235. Additionally, or alternatively, first data structure 225 may be configured to store responses received from measurement devices 235 based on the instructions. In some examples, the instructions may include queries for information associated with measurement devices 235 (e.g., unique identifiers associated with measurement devices 235, module types of battery modules 240, and/or manufacturers of battery modules 240, among other examples). In some situations, controller 205 may be configured to cause the instructions to be provided via first port 215 upon initialization (or upon booting up) of BMS 130. The instructions may be provided in this manner to enable controller 205 to detect whether battery modules 240 are misassembled prior to machine 100 performing an operation. Detecting whether battery modules 240 are misassembled in this manner may prevent damage and/or failure of components of machine 100.

In some examples, controller 205 may generate the instructions based on the battery module information. For example, a number of the instructions may be based on the expected number of battery modules 240 included in battery pack 260 (e.g., identified by the battery module information). Additionally, or alternatively, an order of the instructions may be based on the expected order in which the battery modules 240 are expected to be assembled (e.g., in battery pack 260).

As shown in FIG. 2, first data structure 225 may store four instructions (e.g., CMD1, CMD2, CMD3, and CMD4) based on the battery module information indicating that four battery modules 240 are expected to be included battery pack 260. For example, first data structure 225 may store instructions CMD1 generated for first measurement device 235-1, CMD2 generated for second measurement device 235-2, and so on.

Controller 205 may cause the four instructions to be sequentially provided to measurement devices 235. In some situations, an instruction may be provided to a measurement device 235 via one or more other measurement devices 235. For example, controller 205 may cause a first instruction (CMD4) to be provided to fourth measurement device 235-4 via other measurement devices 235. For instance, the first instruction may be provided to first measurement device 235-1, first measurement device 235-1 may provide the first instruction to second measurement device 235-2, and so on until the first instruction has been provided to fourth measurement device 235-4. Controller 205 may cause a second instruction (CMD3) to be provided to third measurement device 235-3, followed by a third instruction (CMD2) to second measurement device 235-2, and so on.

Under proper assembly of battery pack 260, four responses may be received from measurement devices 235. The four responses may be received sequentially from measurement devices 235 in a manner similar to a manner in which the four instructions were provided to measurement devices 235. The four responses may be received in an order that is reverse with respect to an order in which the instructions were provided. For example, controller 205 may receive a first response from first measurement device 235-1, followed by a second response from second measurement device 235-2, and so on. As an example, second measurement device 235-2 may provide the second response to first measurement device 235-1 and first measurement device 235-1 may provide the second response to controller 205 via first port 215. Controller 205 may use the four responses to determine whether battery modules 240 of battery pack 260 are misassembled, as explained herein.

In some situations, the four instructions may be stored in four entries of first data structure 225. For example, each instruction may be stored in a respective entry of first data structure 225. For instance, in situations where battery modules 240 are properly assembled, each response may be stored in a respective entry in which a corresponding instruction was stored. For example, the first response to CMD4 may be stored in an entry in which CMD4 was stored, a second response to CMD3 may be stored in an entry in which CMD3 was stored, and so on.

As shown in FIG. 2, second port 220 may be associated with a second data structure 230. Second data structure 230 may be configured to store instructions to be provided to measurement devices 235. Additionally, or alternatively, second data structure 230 may be configured to store responses received from measurement devices 235. In some situations, the instructions stored by second data structure 230 may be similar to the instructions stored by first data structure 225. For example, upon initialization of BMS 130, second data structure 230 may store the instructions that include queries for the information associated with measurement devices 235. As shown in FIG. 2, controller 205 has not generated any instructions to be provided via second port 220. Additionally, or alternatively, responses have not been received from measurement devices 235. Accordingly, entries of second data structure 230 may indicate “No Data.”

As shown in FIG. 2, measurement devices 235 may be connected to battery modules 240. For example, first measurement device 235-1 may be connected to first battery module 240-1, second measurement device 235-2 may be connected to second battery module 240-2, and so on. Measurement devices 235 may be configured to monitor operations of battery modules 240. For example, first measurement device 235-1 may monitor an operation of first battery module 240-1 by obtaining one or more measurements from first battery module 240-1. The one or more measurements may include one or more cell voltages of one or more battery cells, or one or more temperatures of the one or more battery cells, among other examples.

A measurement device 235 may include one or more memories. For example, as shown in FIG. 2, first measurement device 235-1 may include a non-volatile memory 245 and a volatile memory 250. As an example, non-volatile memory 245 may include an EEPROM. Non-volatile memory 245 may be configured to store device information associated first measurement device 235-1. For example, the device information may identify a type of module of battery module 240-1, a unique identifier of battery module 240-1, a manufacturer of battery module 240-1, a unique identifier of first measurement device 235-1, among other examples. As an example, the unique identifier of battery module 240-1 may be a serial number of battery module 240-1 and the unique identifier of first measurement device 235-1 may be a serial number of first measurement device 235-1.

Volatile memory 250 may be configured to store instructions received from controller 205. For example, volatile memory 250 may be configured to temporarily store instructions received from controller 205.

In some examples, a battery module 240 may include a plurality of battery cells. The battery cells may be connected in series. In some examples, each battery cell may include fast-charge batteries. For example, a battery cell may include lithium-ion batteries.

As explained above, upon initialization of BMS 130, controller 205 may determine whether battery modules 240 of battery pack 260 are misassembled. In this regard, controller 205 may provide the instructions to measurement devices 235 to obtain unique identifiers associated with measurement devices 235. In some examples, controller 205 may provide the instructions to measurement devices 235 via first port 215 and receive the responses from measurement devices 235 via first port 215, as explained above.

The responses may include unique identifier information identifying unique identifiers associated with measurement devices 235 (e.g., unique identifiers of battery modules 240). In some implementations, controller 205 may determine whether battery modules 240 are misassembled based on an actual order in which the unique identifiers are received. For example, based on the battery module information, controller 205 may determine the expected order in which the battery modules of battery pack 260 are expected to be assembled. For example, the battery module information may indicate an expected order in which the unique identifiers are to be received. Controller 205 may compare the actual order in which the unique identifiers are received and the expected order in which the unique identifiers are received.

Controller 205 may determine that battery modules 240 are improperly assembled (or misassembled) if the actual order is different than the expected order. Controller 205 may provide a notification indicating that the plurality of battery modules are improperly assembled based on determining that battery modules 240 are improperly assembled. For example, controller 205 may provide a notification via the integrated display of operator cabin 120, via a user device of an operator of machine 100, among other examples.

The number and arrangement of devices shown in FIG. 2 are provided as an example. In practice, there may be additional devices, fewer devices, different devices, or differently arranged devices than those shown in FIG. 2. Furthermore, two or more devices shown in FIG. 2 may be implemented within a single device, or a single device shown in FIG. 2 may be implemented as multiple, distributed devices. Additionally, or alternatively, a set of devices (e.g., one or more devices) of the example component may perform one or more functions described as being performed by another set of devices of the example component.

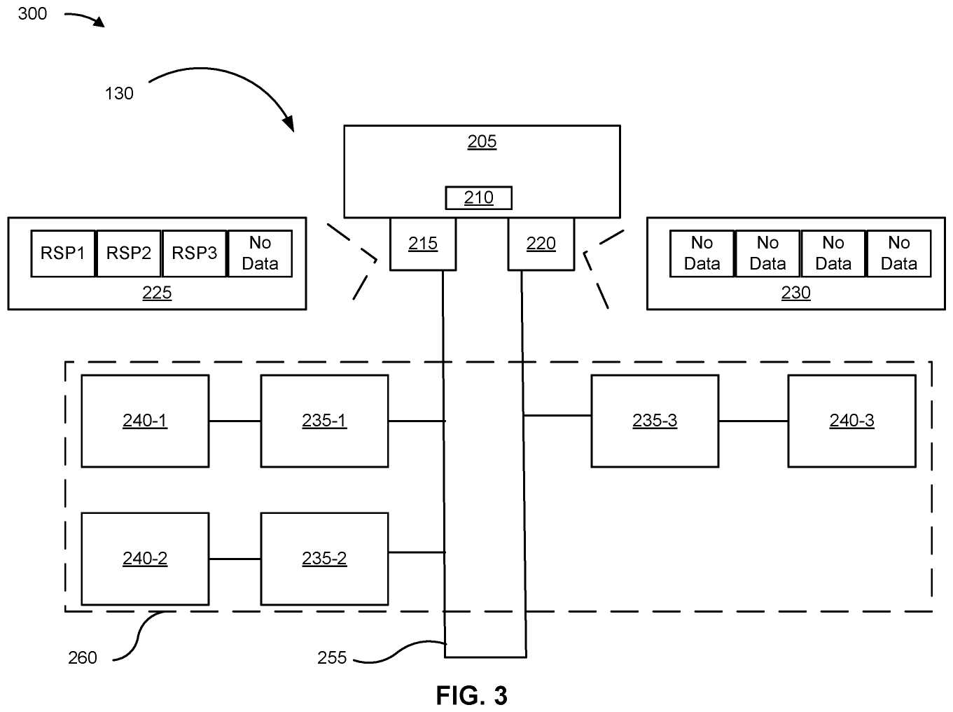

FIG. 3 is a diagram of an example 300 associated with detecting battery pack mis-assembly. As shown in FIG. 3, example 300 includes BMS 130. Elements of BMS 130 have been described above in connection with FIG. 2. As shown in FIG. 3, battery pack 260 includes three battery modules connected to three measurement devices 235.

In FIG. 3, assume controller 205 has provided the four instructions as described above in connection with FIG. 2. Three of the four instructions may be provided to first measurement device 235-1, second measurement device 235-2, and third measurement device 235-3, as explained herein. However, third measurement device 235-3 may be unable to provide an instruction CMD4 to a fourth measurement device expected (by controller 205) to be included in battery pack 260. Accordingly, as shown in FIG. 3, controller 205 may receive three responses based on providing the four instructions. For example, controller 205 may receive a first response RSP1 from first measurement device 235-1 based on CMD1, a second response RSP2 from second measurement device 235-2 based on CMD2, and a third response RSP3 from third measurement device 235-3 based on CMD3.

The first response RSP1 may include a first unique identifier associated with first measurement device 235-1, the second response RSP2 may include a second unique identifier associated with second measurement device 235-2, and the third response RSP3 may include a third unique identifier associated with third measurement device 235-3. The responses may include unique identifier information identifying the unique identifiers associated with first measurement device 235-1, second measurement device 235-2, and third measurement device 235-3.

The three responses may be stored in three entries of first data structure 225. As shown in FIG. 3, no response may be received from the fourth measurement device and, accordingly, a fourth entry of first data structure 225 may not include a response. In this regard, controller 205 may determine that a response has not been received from the fourth measurement device.

The number and arrangement of devices shown in FIG. 3 are provided as an example. In practice, there may be additional devices, fewer devices, different devices, or differently arranged devices than those shown in FIG. 3. Furthermore, two or more devices shown in FIG. 3 may be implemented within a single device, or a single device shown in FIG. 3 may be implemented as multiple, distributed devices. Additionally, or alternatively, a set of devices (e.g., one or more devices) of the example component may perform one or more functions described as being performed by another set of devices of the example component.

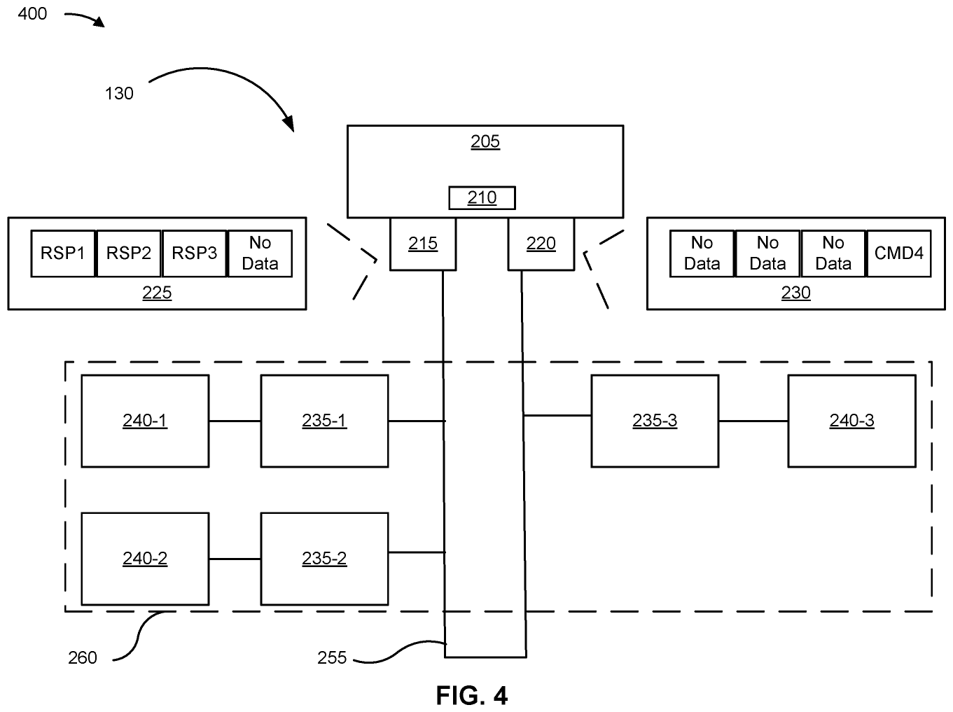

FIG. 4 is a diagram of an example 400 associated with detecting battery pack mis-assembly. As shown in FIG. 4, example 400 includes BMS 130. Elements of BMS 130 have been described above in connection with FIG. 2. Continuing with the example in FIG. 3, based on determining that a response has not been received from the fourth measurement device after providing CMD4 via first port 215, controller 205 may determine to attempt to provide CMD4 via second port 220. In this regard, controller 205 may generate CMD4.

As shown in FIG. 4, controller 205 may store CMD4 in an entry of second data structure 230. The entry of second data structure 230 may be based on an expected order of measurement devices 235 and battery modules 240 on data bus 255. The fourth measurement device may be expected to be a first measurement device that receives CMD4. For example, the entry of second data structure 230 may be entry associated with the first measurement device that is expected to receive CMD4 when CMD4 is provided via second port 220. Controller 205 may cause CMD4 to be provided to the fourth measurement device.

As indicated above, FIG. 4 is provided as an example. Other examples may differ from what was described in connection with FIG. 4.

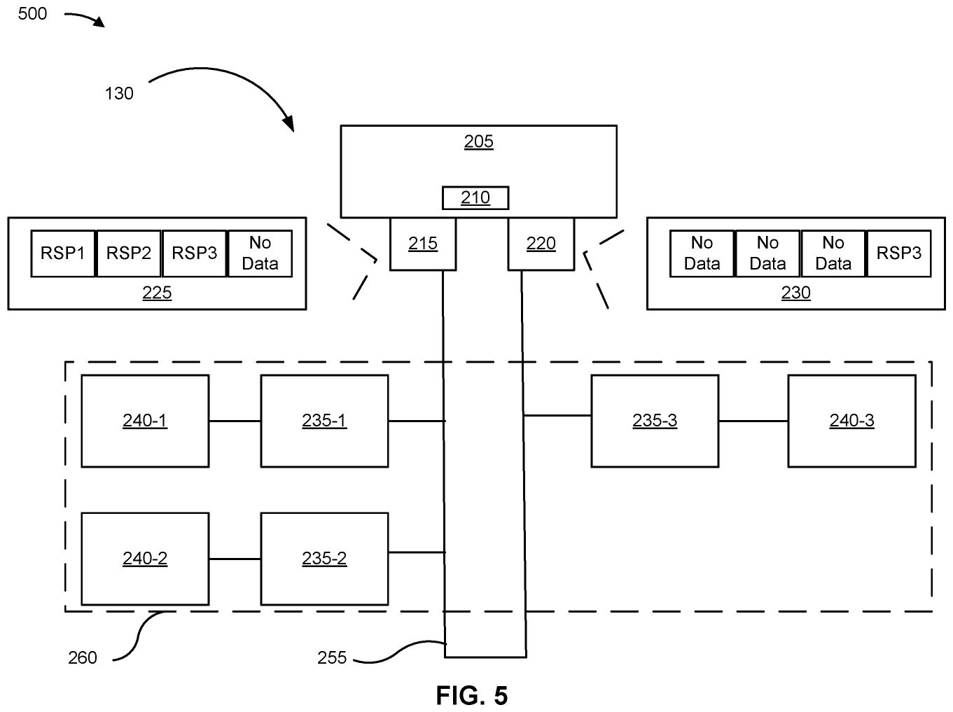

FIG. 5 is a diagram of an example 500 associated with detecting battery pack mis-assembly. As shown in FIG. 5, example 500 includes BMS 130. Elements of BMS 130 have been described above in connection with FIG. 2. Continuing with the example in FIG. 4, the first measurement device that receives is third measurement device 235-3 (because the fourth measurement device is not connected to data bus 255). Accordingly, third measurement device 235-3 may provide the third response RSP3 via second port 220. The third response may include unique identifier information identifying the third unique identifier associated with third measurement device 235-3. The third response RSP3 may be stored in the entry of second data structure 230 that previously stored CMD4.

Controller 205 may analyze the entries of first data structure 225 and second data structure 230. Based on analyzing the entries, controller 205 may determine that at least one unique identifier, identified by the unique identifier information received via first port 215, is also identified by the unique identifier information received via second port 220. For example, controller 205 may determine that a unique identifier identified in response RSP3 received via first port 215 was also identified by the unique identifier information received via second port 220, instead of identifying a unique identifier associated with a fourth measurement device. Accordingly, controller 205 may determine that battery modules 240 are improperly assembled (or misassembled). Based on determining that battery modules 240 are improperly assembled, controller 205 may provide a notification, as explained herein.

As indicated above, FIG. 5 is provided as an example. Other examples may differ from what was described in connection with FIG. 5.

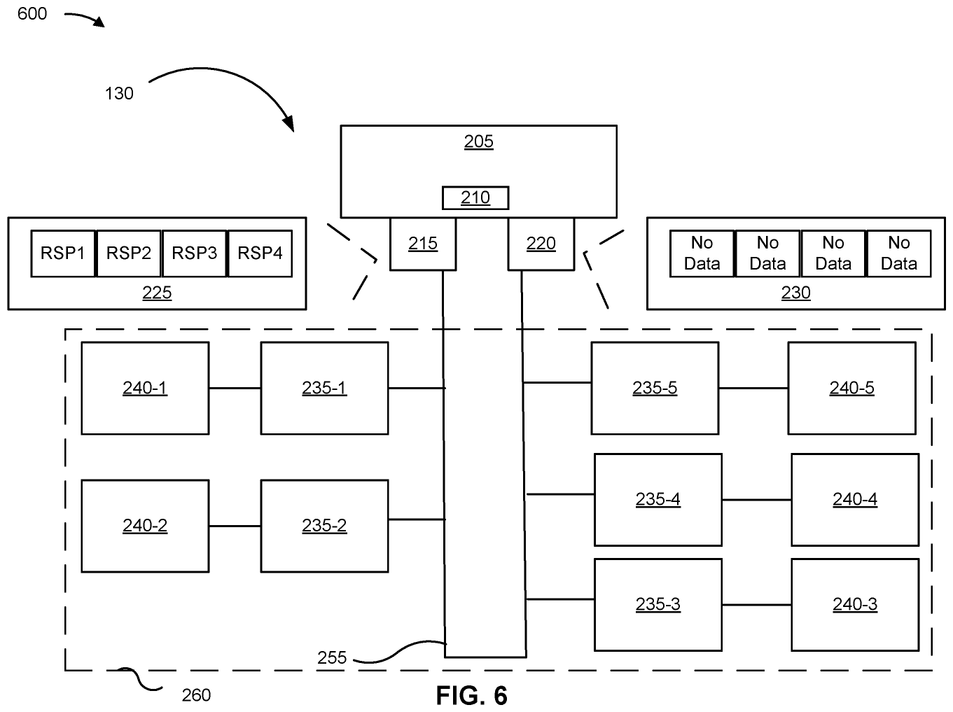

FIG. 6 is a diagram of an example 600 associated with detecting battery pack mis-assembly. As shown in FIG. 6, example 600 includes BMS 130. Elements of BMS 130 have been described above in connection with FIG. 2. As shown in FIG. 6, battery pack 260 includes five battery modules 240 connected to five measurement devices 235.

In FIG. 6, assume controller 205 has provided the four instructions as described above in connection with FIG. 2. The four instructions may be provided to first measurement device 235-1, second measurement device 235-2, third measurement device 235-3, and fourth measurement device 235-4, as explained herein. Accordingly, as shown in FIG. 4, controller 205 may receive four responses, via first port 215, based on providing the four instructions. For example, controller 205 may receive a first response RSP1 from first measurement device 235-1 based on CMD1, a second response RSP2 from second measurement device 235-2 based on CMD2, a third response RSP3 from third measurement device 235-3 based on CMD3, and a fourth response RSP4 from fourth measurement device 235-4 based on CMD4. As shown in FIG. 4, the responses may be stored in entries of first data structure 225, as explained herein.

The number and arrangement of devices shown in FIG. 6 are provided as an example. In practice, there may be additional devices, fewer devices, different devices, or differently arranged devices than those shown in FIG. 6. Furthermore, two or more devices shown in FIG. 6 may be implemented within a single device, or a single device shown in FIG. 6 may be implemented as multiple, distributed devices. Additionally, or alternatively, a set of devices (e.g., one or more devices) of the example component may perform one or more functions described as being performed by another set of devices of the example component.

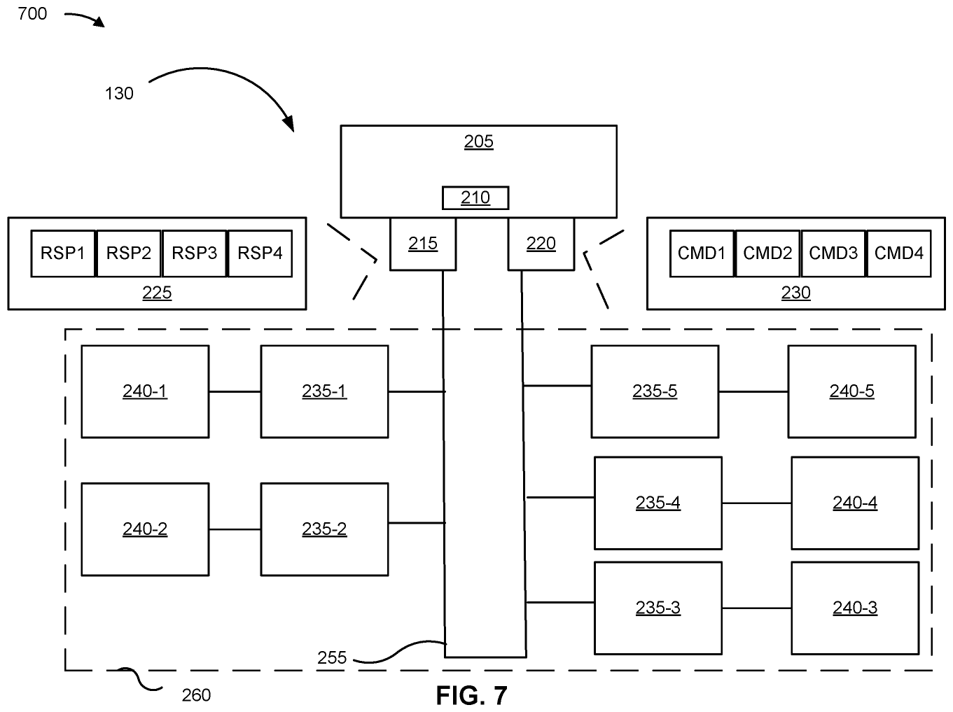

FIG. 7 is a diagram of an example 700 associated with detecting battery pack mis-assembly. As shown in FIG. 7, example 400 includes BMS 130. Elements of BMS 130 have been described above in connection with FIG. 2. Continuing the example described in FIG. 6, controller 205 may generate the instructions generated in FIG. 2 for transmission to measurement devices 235 via second port 220.

As shown in FIG. 7, controller 205 may cause the instructions to be stored in entries of second data structure 230, as described herein. Controller 205 may cause the instructions to be provided from second data structure 230 to measurement devices 235 via second port 220. In this regard, because battery pack 260 includes a fifth battery module 240-5 connected to a fifth measurement device 235-5, CMD1 may be provided to second measurement device 235-2 instead of being provided to first measurement device 235-1, CMD2 may be provided to third measurement device 235-3 instead of being provided to second measurement device 235-2, and so on.

As indicated above, FIG. 7 is provided as an example. Other examples may differ from what was described in connection with FIG. 7.

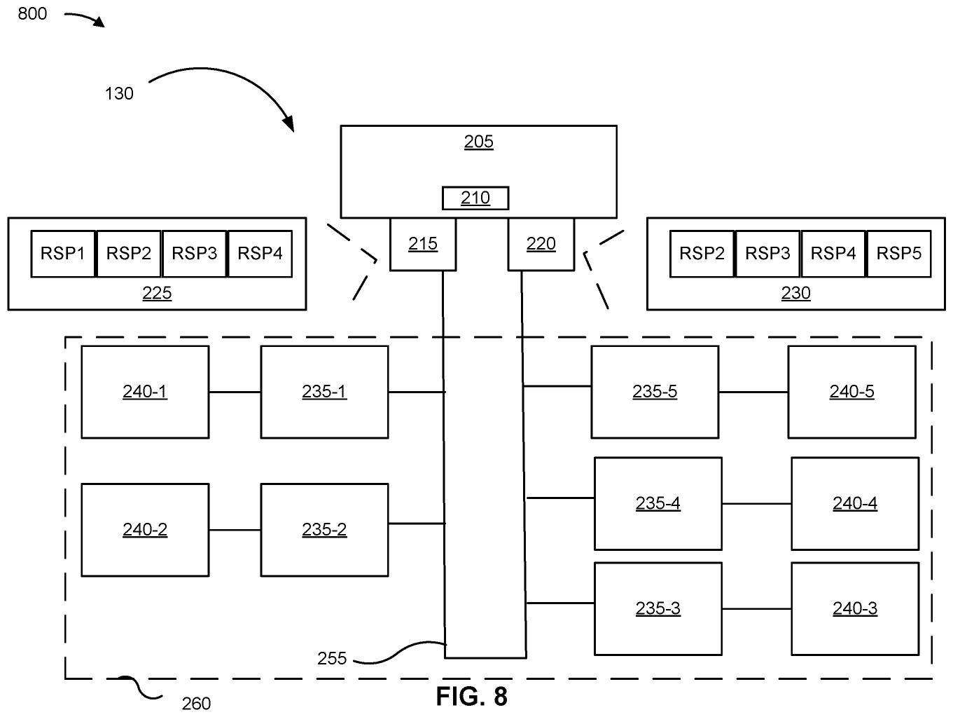

FIG. 8 is a diagram of an example 800 associated with detecting battery pack mis-assembly. As shown in FIG. 8, example 800 includes BMS 130. Elements of BMS 130 have been described above in connection with FIG. 2. Based on providing the instructions as described in FIG. 7, controller 205 may receive responses from four of the five measurement devices 235. For example, controller 205 may receive RSP2 from second measurement device 235-2, RSP3 from third measurement device 235-3, RSP4 from fourth measurement device 235-4, and RSP5 from fifth measurement device 235-5. The responses may be stored in the entries of second data structure 230 as shown in FIG. 8.

Controller 205 may analyze the entries of first data structure 225 and second data structure 230. Based on analyzing the entries, controller 205 may determine that at least one unique identifier, identified by the unique identifier information received via first port 215, is not also identified by the unique identifier information received via second port 220. For example, controller 205 may determine that a unique identifier identified in response RSP5 was not identified by the unique identifier information received via first port 215. Accordingly, controller 205 may determine that battery modules 240 are improperly assembled (or misassembled). Based on determining that battery modules 240 are improperly assembled, controller 205 may provide a notification, as explained herein.

As indicated above, FIG. 8 is provided as an example. Other examples may differ from what was described in connection with FIG. 8.

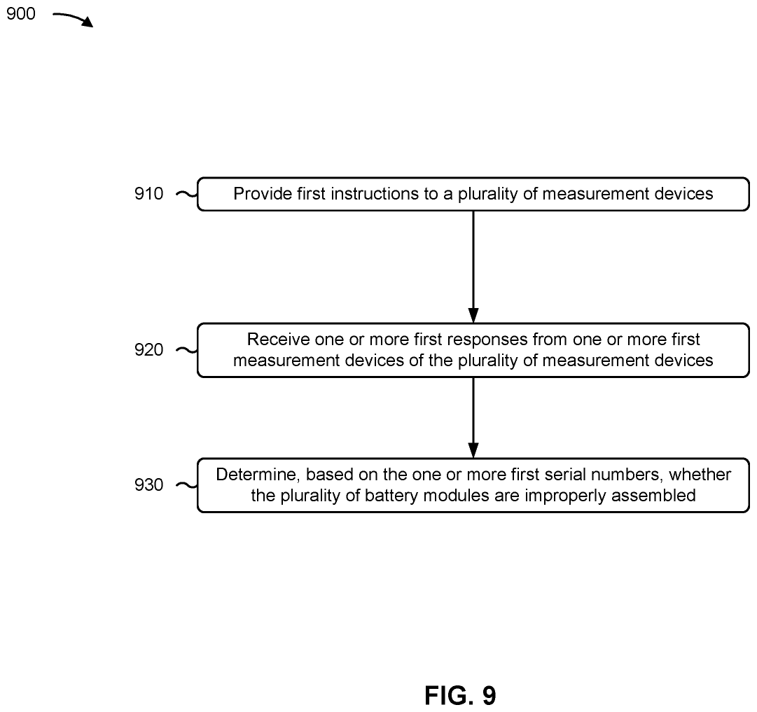

FIG. 9 is a flowchart of an example process 900 relating to detecting battery pack mis-assembly. In some implementations, one or more process blocks of FIG. 9 may be performed by a controller (e.g., controller 205). In some implementations, one or more process blocks of FIG. 9 may be performed by another device or a group of devices separate from or including the battery management system configured, such as measurement devices (e.g., measurement devices 235).

As shown in FIG. 9, process 900 may include providing first instructions to a plurality of measurement devices (block 910). For example, the controller may provide first instructions to a plurality of measurement devices, as described above. In some implementations, the plurality of measurement devices are configured to obtain measurements from a plurality of battery modules of a battery pack.

As further shown in FIG. 9, process 900 may include receiving one or more first responses from one or more first measurement devices of the plurality of measurement devices based on providing the first instructions (block 920). For example, the controller may receive one or more first responses from one or more first measurement devices of the plurality of measurement devices based on providing the first instructions, as described above. In some implementations, the one or more first responses include first unique identifier information identifying one or more first unique identifiers associated with the one or more first measurement devices.

As further shown in FIG. 9, process 900 may include determining, based on the one or more first unique identifiers, whether the plurality of battery modules are improperly assembled (block 930). For example, the controller may determine, based on the one or more first unique identifiers, whether the plurality of battery modules are improperly assembled, as described above.

In some implementations, the one or more first unique identifiers are a first plurality of unique identifiers, and wherein the method further comprises determining that an order of the first plurality of unique identifiers is incorrect, and determining that the plurality of battery modules are improperly assembled based on determining that the order of the first plurality of unique identifiers is incorrect.

In some implementations, process 900 includes providing second instructions to the plurality of measurement devices, receiving one or more second responses from one or more second measurement devices of the plurality of measurement devices based on providing the second instructions, wherein the one or more second responses include second unique identifier information identifying one or more second unique identifiers associated with the one or more second measurement devices, comparing the first unique identifier information and the second unique identifier information, and determining whether the plurality of battery modules are improperly assembled based on comparing the first unique identifier information and the second unique identifier information.

In some implementations, process 900 includes determining that at least one unique identifier, identified by the first unique identifier information, is also identified by the second unique identifier information, determining that a first number of battery modules, of the plurality of battery modules, exceeds a second number of battery modules expected to be included in the battery pack, and determining that the plurality of battery modules are improperly assembled based on determining that the first number of battery modules exceeds the second number of battery modules.

In some implementations, process 900 includes determining that at least one unique identifier, identified by the first unique identifier information, is not also identified by the second unique identifier information, determining that a first number of battery modules, of the plurality of battery modules, is less than a second number of battery modules expected to be included in the battery pack, and determining that the plurality of battery modules are improperly assembled based on determining that the first number of battery modules is less than the second number of battery modules.

In some implementations, process 900 includes determining that the plurality of battery modules are improperly assembled, and providing a notification indicating that the plurality of battery modules are improperly assembled based on determining that the plurality of battery modules are improperly assembled.

Although FIG. 9 shows example blocks of process 900, in some implementations, process 900 may include additional blocks, fewer blocks, different blocks, or differently arranged blocks than those depicted in FIG. 9. Additionally, or alternatively, two or more of the blocks of process 900 may be performed in parallel.

### INDUSTRIAL APPLICABILITY

Implementations described herein are directed to a controller, of a BMS, that is configured to detect whether battery modules (240) are misassembled. The controller (205) may determine whether the battery modules (240) are misassembled based on receiving unique identifier information received from measurement devices (235) connected to the battery modules (240). For example, the unique identifier information may identify unique identifiers associated with the measurement devices (235). As an example, the unique identifiers may be unique identifiers of the battery modules (240) connected to the measurement devices (235).

Currently, existing controllers, of BMSs, are unable to detect that the battery modules are misassembled. The inability to detect mis-assembly of the battery modules may cause one or more components of a work machine to operate in an undesired manner. For example, the inability to detect mis-assembly of the battery modules may lead to inaccurate battery state estimation, battery damage, and/or battery failure.

By determining whether battery modules are misassembled, implementations described herein may prevent components of a work machine from operate in an undesired manner. For example, implementations described herein may prevent inaccurate battery state estimations, battery damage, and/or battery failure.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations cannot be combined. Even though particular combinations of features are recited in the claims and/or disclosed in the specification, these combinations are not intended to limit the disclosure of various implementations. Although each dependent claim listed below may directly depend on only one claim, the disclosure of various implementations includes each dependent claim in combination with every other claim in the claim set.

As used herein, “a,” “an,” and a “set” are intended to include one or more items, and may be used interchangeably with “one or more.” Further, as used herein, the article “the” is intended to include one or more items referenced in connection with the article “the” and may be used interchangeably with “the one or more.” Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. A battery management system configured to detect mis-assembly of a battery pack, the battery management system comprising:
a data bus;
a plurality of measurement devices configured to obtain measurements from a plurality of battery modules of the battery pack,
wherein the plurality of measurement devices are connected to the data bus; and a controller, connected to the data bus, configured to:
provide first instructions to the plurality of measurement devices,
receive one or more first responses from one or more first measurement devices of the plurality of measurement devices based on providing the first instructions, wherein the one or more first responses include first unique identifier information identifying one or more first unique identifiers associated with the one or more first measurement devices;
provide second instructions to the plurality of measurement devices,
receive one or more second responses from one or more second measurement devices of the plurality of measurement devices based on providing the second instructions, wherein the one or more second responses include second unique identifier information identifying one or more second unique identifiers associated with the one or more second measurement devices; and
determine whether the plurality of battery modules are improperly assembled based on the first unique identifier information and the second unique identifier information.

2. The battery management system of claim 1, wherein the controller is further configured to:
determine that at least one unique identifier, identified by the first unique identifier information, is also identified by the second unique identifier information;
determine that a first number of battery modules, of the plurality of battery modules, exceeds a second number of battery modules expected to be included in the battery pack; and
determine that the plurality of battery modules are improperly assembled based on determining that the first number of battery modules exceeds the second number of battery modules.

3. The battery management system of claim 1, wherein the controller is further configured to:
determine that at least one unique identifier, identified by the first unique identifier information, is not also identified by the second unique identifier information;
determine that a first number of battery modules, of the plurality of battery modules, is less than a second number of battery modules expected to be included in the battery pack; and
determine that the plurality of battery modules are improperly assembled based on determining that the first number of battery modules is less than the second number of battery modules.

4. The battery management system of claim 1, wherein the one or more first unique identifiers are a first plurality of unique identifiers, and
wherein the controller is further configured to:
determine that an order of the first plurality of unique identifiers is incorrect; and
determine that the plurality of battery modules are improperly assembled based on determining that the order of the first plurality of unique identifiers is incorrect.

5. The battery management system of claim 1, wherein the controller is further configured to:
determine, based on the one or more first responses, that at least one measurement device of the plurality of measurement devices has not provided a response; and
provide the second instructions based on determining that the at least one measurement device has not provided a response.

6. The battery management system of claim 1, wherein the data bus is connected to a first port of the controller and connected to a second port of the controller, and
wherein the controller is configured to provide the first instructions via the first port and provide the second instructions via the second port.

7. The battery management system of claim 6, wherein the controller is configured to receive the one or more first responses via the first port and receive the one or more second responses via the second port.

8. A machine, comprising:
a data bus;
a plurality of measurement devices configured to obtain measurements from a plurality of battery modules of a battery pack,
wherein the plurality of measurement devices are connected to the data bus; and a controller, connected to the data bus, configured to:
provide first instructions to the plurality of measurement devices,
receive one or more first responses from one or more first measurement devices of the plurality of measurement devices based on providing the first instructions,
wherein the one or more first responses include first unique identifier information identifying one or more first unique identifiers associated with the one or more first measurement devices;
provide second instructions to the plurality of measurement devices,
receive one or more second responses from one or more second measurement devices of the plurality of measurement devices based on providing the second instructions,
wherein the one or more second responses include second unique identifier information identifying one or more second unique identifiers associated with the one or more second measurement devices;
compare the first unique identifier information and the second unique identifier information; and
determine whether the plurality of battery modules are improperly assembled based on comparing the first unique identifier information and the second unique identifier information.

9. The machine of claim 8, wherein the data bus is connected to a first port of the controller and connected to a second port of the controller, and
wherein the controller is further configured to:
store the first unique identifier information in a first data structure associated with the first port; and
store the second unique identifier information in a second data structure associated with the second port.

10. The machine of claim 8, wherein a measurement device, of the plurality of measurement devices, includes a non-volatile memory, and
wherein the non-volatile memory is configured to store a unique identifier of the measurement device.

11. The machine of claim 8, wherein the controller is further configured to:
determine that at least one unique identifier, identified by the first unique identifier information, is also identified by the second unique identifier information; and
determine that a first number of battery modules, of the plurality of battery modules, exceeds a second number of battery modules expected to be included in the battery pack; and
determine that the plurality of battery modules are improperly assembled based on determining that the first number of battery modules exceeds the second number of battery modules.

12. The machine of claim 8, wherein the controller is further configured to:
determine that at least one unique identifier, identified by the first unique identifier information, is not also identified by the second unique identifier information;
determine that a first number of battery modules, of the plurality of battery modules, is less than a second number of battery modules expected to be included in the battery pack; and
determine that the plurality of battery modules are improperly assembled based on determining that the first number of battery modules is less than the second number of battery modules.

13. The machine of claim 8, wherein the controller is further configured to:
determine that the plurality of battery modules are improperly assembled; and
provide a notification indicating that the plurality of battery modules are improperly assembled based on determining that the plurality of battery modules are improperly assembled.

14. The machine of claim 8, wherein the controller is further configured to:
determine, based on the one or more first responses, that at least one measurement device of the plurality of measurement devices has not provided a response; and
provide the second instructions based on determining that the at least one measurement device has not provided a response.

15. A method performed by a controller, the method comprising:
providing first instructions to a plurality of measurement devices,
wherein the plurality of measurement devices are configured to obtain measurements from a plurality of battery modules of a battery pack;
receiving one or more first responses from one or more first measurement devices of the plurality of measurement devices based on providing the first instructions,
wherein the one or more first responses include first unique identifier information identifying one or more first unique identifiers associated with the one or more first measurement devices; and
determining, based on the one or more first unique identifiers, whether the plurality of battery modules are improperly assembled.

16. The method of claim 15, wherein the one or more first unique identifiers are a first plurality of unique identifiers, and
wherein the method further comprises:
determining that an order of the first plurality of unique identifiers is incorrect; and
determining that the plurality of battery modules are improperly assembled based on determining that the order of the first plurality of unique identifiers is incorrect.

17. The method of claim 15, further comprising:
providing second instructions to the plurality of measurement devices;
receiving one or more second responses from one or more second measurement devices of the plurality of measurement devices based on providing the second instructions,
wherein the one or more second responses include second unique identifier information identifying one or more second unique identifiers associated with the one or more second measurement devices;
comparing the first unique identifier information and the second unique identifier information; and
determining whether the plurality of battery modules are improperly assembled based on comparing the first unique identifier information and the second unique identifier information.

18. The method of claim 17, further comprising:
determining that at least one unique identifier, identified by the first unique identifier information, is also identified by the second unique identifier information;
determining that a first number of battery modules, of the plurality of battery modules, exceeds a second number of battery modules expected to be included in the battery pack; and
determining that the plurality of battery modules are improperly assembled based on determining that the first number of battery modules exceeds the second number of battery modules.

19. The method of claim 17, further comprising:
determining that at least one unique identifier, identified by the first unique identifier information, is not also identified by the second unique identifier information;
determining that a first number of battery modules, of the plurality of battery modules, is less than a second number of battery modules expected to be included in the battery pack; and
determining that the plurality of battery modules are improperly assembled based on determining that the first number of battery modules is less than the second number of battery modules.

20. The method of claim 15, further comprising:
determining that the plurality of battery modules are improperly assembled; and
providing a notification indicating that the plurality of battery modules are improperly assembled based on determining that the plurality of battery modules are improperly assembled.
